(19) United States
(12) Patent Application Publication
(10) Pub. No.: US 2025/0079293 A1
(43) Pub. Date: Mar. 6, 2025

(54) SEMICONDUCTOR DEVICE AND FABRICATING METHOD THEREOF

(71) Applicant: UNITED MICROELECTRONICS CORP., Hsin-Chu City (TW)

(72) Inventors: Tai-Cheng Hou, Tainan City (TW); Da-Jun Lin, Kaohsiung City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/379,670

(22) Filed: Oct. 13, 2023

(30) Foreign Application Priority Data
Aug. 31, 2023 (TW) 112133011

(51) Int. Cl. H01L 23/522; H01L 21/768

(52) U.S. Cl. CPC H01L 23/5226; H01L 21/76805; H01L 21/76807; H01L 21/7682

(57) ABSTRACT

A semiconductor device and a method of fabricating the same, includes at least one dielectric layer, a conductive structure, and a first insulator. The at least one dielectric layer includes a stacked structure having a low-k dielectric layer, an etching stop layer, and a conductive layer between the low-k dielectric layer and the etching stop layer. The conductive structure is disposed in the first dielectric layer. The first insulator is disposed between the conductive layer and the conductive structure.

### BACKGROUND OF THE INVENTION

### 1. Field of the Invention

The present disclosure relates generally to a semiconductor device and a method of fabricating the same, and more particularly to a semiconductor device including a dielectric layer, and a method of fabricating the same.

### 2. Description of the Prior Art

An integrated circuit (IC) is constructed by various active components and interconnection structures formed on a substrate or in different films. Generally speaking, the fabrication of the interconnection structures is firstly carried out by etching a dielectric layer to form a through hole or a circuit pattern in the dielectric layer, and filling in the through hole or the circuit pattern with a conductive material such as copper followed by planarizing the conductive material. In the back-end processes of the semiconductor devices, the frequent use of plasma easily leads to accumulation of redundant charges on the conductive material filled in the through hole or the circuit pattern, and the excessive charges often results in unnecessary currents which may enters the circuit from the conductive material, penetrates the gate oxide and leads to a threshold voltage shift. The aforementioned issues will cause damage to the components in the front-end process, referring to a plasma induced damage (PID) caused by Antenna effect.

In the advanced semiconductor industry, as the continuously shrinking dimension and the continuously increasing integration, the operation performance of semiconductor devices is deeply affected by the Antenna effect. Accordingly, the layout of the circuit is required to meet the appropriate Antenna ratio (AR), that is, the ratio between the exposed area of the metal wire and the area of the gate dielectric layer. The semiconductor device is less affected by the Antenna effect if the AR is smaller, and the yield and reliability of the semiconductor device may be probably improved thereby. However, the existing AR limitation leads to the increasing difficulty and complexity of the circuit design and manufacturing process, there is still a certain chance that the current will concentrate on the transistor with smaller resistance when using the improved design such as transistor parallel connection, which still cannot effectively solve the problems caused by Antenna effect. Therefore, the improvement of the existing technology is still a crucial subject to people in the related arts.

### SUMMARY OF THE INVENTION

An object of the present disclosure is to provide a semiconductor device and a method of fabricating the same, where a conductive layer is additionally disposed within a dielectric layer, and an insulator is further disposed between a conductive structure and the conductive layer both within the dielectric layer, thereby guiding the unstable charges accumulated on the conductive structure to an external environment via the conductive layer. Through these manners, the semiconductor device and the fabricating method thereof in the present disclosure are no longer required to meet the existing Antenna ratio (AR) limitation like AR2000, and which are able to achieve a better reliability and yield under an increased AR, to gain an optimized operating performance.

To achieve the aforementioned objects, the present disclosure provides a semiconductor device including at least one dielectric layer, a conductive structure and a first insulator. The at least one dielectric layer includes a stacked structure having a low-k dielectric layer and an etching stop layer, and a conductive layer is disposed between the low-k dielectric layer and the etching stop layer. The conductive structure is disposed in the first dielectric layer. The first insulator is disposed between the conductive layer and the conductive structure.

To achieve the aforementioned objects, the present disclosure provides a method of fabricating a semiconductor device including the following steps. Firstly, at least one dielectric layer is formed, and the at least one dielectric layer includes a stacked structure including a low-k dielectric layer and an etching stop layer, and a conductive layer is disposed between the low-k dielectric layer and the etching stop layer. A conductive structure is formed in the first dielectric layer. A first insulator is formed between the conductive layer and the conductive structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a cross-sectional view of a semiconductor device according to a first embodiment of the present disclosure.

FIG. 2 to FIG. 4 illustrate schematic diagrams of a method of fabricating a semiconductor device according to a first embodiment of the present disclosure, in which:

FIG. 2 is a schematic cross-sectional view of a semiconductor device after forming a stacked structure;

FIG. 3 is a schematic cross-sectional view of a semiconductor device after forming a through hole; and

FIG. 4 is a schematic cross-sectional view of a semiconductor device after forming an insulator.

FIG. 5 illustrates a schematic diagram of a cross-sectional view of a semiconductor device according to a second embodiment of the present disclosure.

FIG. 6 illustrates a schematic diagram of a cross-sectional view of a semiconductor device according to a third embodiment of the present disclosure.

FIG. 7 illustrates a schematic diagram of a cross-sectional view of a semiconductor device according to a fourth embodiment of the present disclosure.

FIG. 8 illustrates a schematic diagram of a cross-sectional view of a semiconductor device according to a fifth embodiment of the present disclosure.

FIG. 9 illustrates a schematic diagram of a cross-sectional view of a semiconductor device according to a sixth embodiment of the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

Please refer to FIG. 1, which illustrates a semiconductor device 10 according to a first embodiment of the present disclosure. The semiconductor device 10 includes at least one dielectric layer 120, a conductive structure 130, a conductive layer 124, and a first insulator 128. The dielectric layer 120 further includes a stacked structure including an etching stop layer 122 and a low-k dielectric layer 126. The conductive structure 130 is disposed within the dielectric layer 120, for example including any components being made of a conductive material like a conductive line, a plug, a metal line or a redistribution layer (RDL), but is not limited thereto. In the present embodiment, the conductive structure 130 for example includes a dual damascene structure, but is not limited thereto. It is noted that the conductive layer 124 is disposed within the stacked structure, between the etching stop layer 122 and the low-k dielectric layer 126, and the first insulator 128 is additionally disposed between the conductive layer 124 and the conductive structure 130, to prevent the conductive layer 124 from directly connecting the conductive structure 130 that leads to short circuit. Through these arrangements, the conductive layer 124 is disposed in the middle of the stacked structure of the dielectric layer 120, with the conductive layer 124 not directly in contact with the top surface or the bottom surface of the dielectric layer 120, thereby dispersing or guiding unstable charges accumulated on the conductive structure 130 to the external environment or to ground through the conductive layer 124, so as to reduce the structural damages to the semiconductor device 10 caused by plasma used in the back-end process, and thus further avoid the Antenna effect.

In one embodiment, the conductive layer 124 for example includes a suitable conductive material, such as a metal material like titanium (Ti), tantalum (Ta), aluminum (Al), copper (Cu) or tungsten (W), or a semiconductor material like doped silicon, doped germanium, indium zinc oxide (IZO) or indium gallium zinc oxide (IGZO), but not limited thereto, and the first insulator 128 for example includes the conductive material having undergone an insulation process, such as a metal oxides like titanium dioxide (TiO₂), tantalum dioxide (TaO₂), aluminum oxide (Al₂O₃) or copper oxide (CuO), or a metal nitrides like aluminum nitride or copper nitride, or an oxide semiconductor/a nitride semiconductor like silicon oxide, germanium oxide, silicon nitride or germanium nitride, but not limited thereto. The first insulator 128 preferably includes a thickness T1 between 50 angstroms and 300 angstroms in a horizontal direction, to effectively insulate the conductive layer 124 from the conductive structure 130 without excessively increasing the dielectric constant of the dielectric layer 120. In another embodiment, the low-k dielectric layer 126 for example includes a dielectric material having a dielectric constant lower than 3, preferably in the range of 2.5 to 2.9, such as including fluorinated silica glass (FSG), silicon carbide oxide (SiCOH), porous carbon oxide or spin-coated silicon glass, but not limited thereto. The etching stop layer 122 for example includes a dielectric material having a dielectric constant greater than that of the low-k dielectric layer 126, such as including nitrogen doped silicon carbide (SiCN), but not limited thereto.

Further in view of FIG. 1, the etching stop layer 122, the conductive layer 124 and the low-k dielectric layer 126 are stacked sequentially from bottom to top on the substrate 100. The substrate 100 for example includes a silicon substrate, a silicon-containing substrate (for example including silicon carbide or silicon germanium), or silicon-on-insulator substrate, and at least one shallow trench isolation 102 is disposed in the substrate 100, to surround and to define a plurality of active areas (not shown in the drawings) in the substrate 100, but is not limited thereto. The semiconductor device 10 further includes a dielectric layer 110 and a gate structure 140 between the dielectric layer 120 and the substrate 100. The gate structure 140 is disposed on the substrate 100, to further include a gate dielectric layer 142 and a gate electrode 144 stacked sequentially on a top surface of the substrate 100, and two source/drain electrodes 146 are disposed within the substrate 100, at two sides of the gate structure 140.

The dielectric layer 110 is disposed on the gate structure 140 and the substrate 100, and a plug 112 is disposed in the dielectric layer 110 to electrically connect the gate structure 140 underneath, and the first conductive structure 130 thereabove at the same time. With these arrangements, the dielectric layer 110 is configured as an interlayer dielectric (ILD) layer of the semiconductor device 10 when the plug 112 serving as a contact plug or a zero-layer metal interconnection (M0) of the semiconductor device 10, and the dielectric layer 120 is configured as an inter-metal dielectric (IMD) layer of the semiconductor device 10 when the first conductive structure 130 serving as a first-layer metal interconnection (M1). It is noted that, the aforementioned dielectric layers and the interconnections are sequentially disposed over the gate structure 140, such that, the gate structure 140 may enable to be electrically connected to other active elements and/or passive elements through other connection, thereby achieving the required performances.

According to the semiconductor device 10 of the present embodiment, as the conductive layer 124 is disposed within the IMD layer (namely the dielectric layer 120), with the unstable charges accumulated on the interconnection (namely conductive structure 130) being dispersed or being guided to the external environment or to ground via the conductive layer 124, thereby reducing the possibility of structural damages caused by plasma used in the back-end process. In this way, the semiconductor device 10 of the present embodiment enables to improve the Antenna effect, and the Antenna ratio (AR) of the semiconductor device 10 is no longer required to meet the existing AR limitation like AR2000. Accordingly, the semiconductor device 10 of the present embodiment is able to gain an improved reliability and yield, and thus to achieve better functions and performances.

In order to make people skilled in the art of the present disclosure easily understand the semiconductor device 10 of the present disclosure, the fabricating method of the semiconductor device 10 in the present disclosure will be further described below.

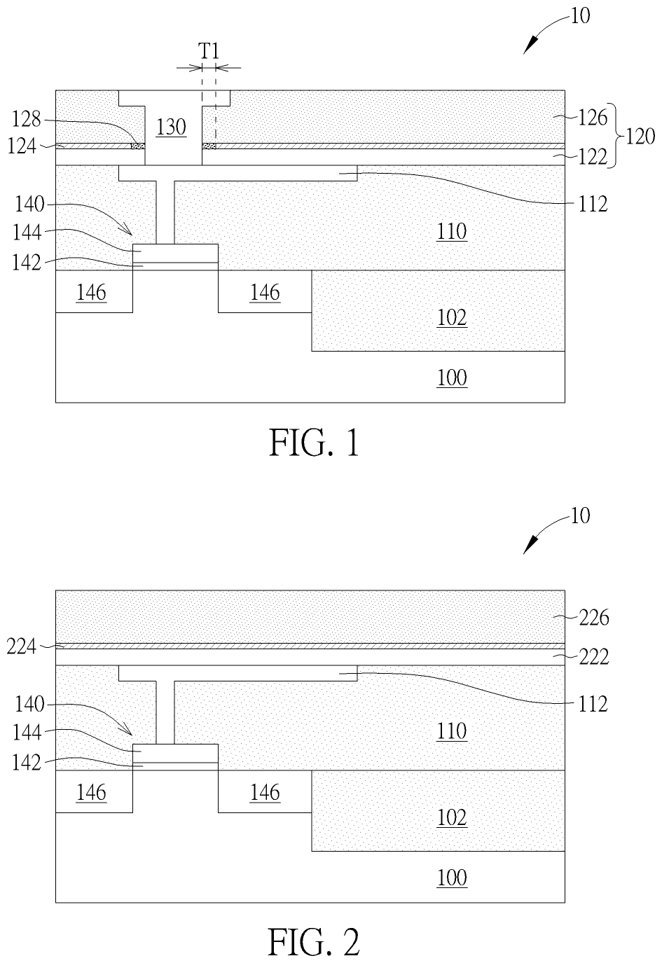

Please refer to FIG. 2 and FIG. 4, illustrating schematic diagrams of a fabricating method of the semiconductor device 10 according to the first embodiment in the present disclosure. Firstly, as shown in FIG. 2, the substrate 100 is provided, and the shallow trench isolation 102 is formed in the substrate 100. The gate dielectric layer 142 and the gate electrode layer 144 are sequentially formed on the substrate 100, to form the gate structure 140. The two source/drain electrodes 146 are formed in the substrate 100, at two sides of the gate structure 140 respectively. Next, the dielectric layer 110 is formed on the substrate 100, covering the substrate 100 and the gate structure 140, and the plug 112 is then formed in the dielectric layer 110.

As shown in FIG. 2, an etching stop material layer 222, a conductive material layer 224, and a low-k dielectric material layer 226 are sequentially formed on the dielectric layer 110 and the plug 112. In one embodiment, the etching stop material layer 222 for example includes a dielectric material having a greater dielectric constant than that of the low-k dielectric material layer 226, for example including nitrogen doped carbide, but not limited thereto. The low-k dielectric material layer 226 for example includes a dielectric material having a dielectric constant lower than 3, and preferably in a range of 2.5 to 2.9, for example being FSG, SiCOH, porous carbon oxide or spin-coated silicon glass, but not limited thereto. In another embodiment, the conductive material layer 224 for example includes any suitable conductive material, such as a metal material like Ti, Ta, Al, Cu or W, or a semiconductor material like doped silicon, doped germanium, indium zinc oxide or indium gallium zinc oxide, but not limited thereto.

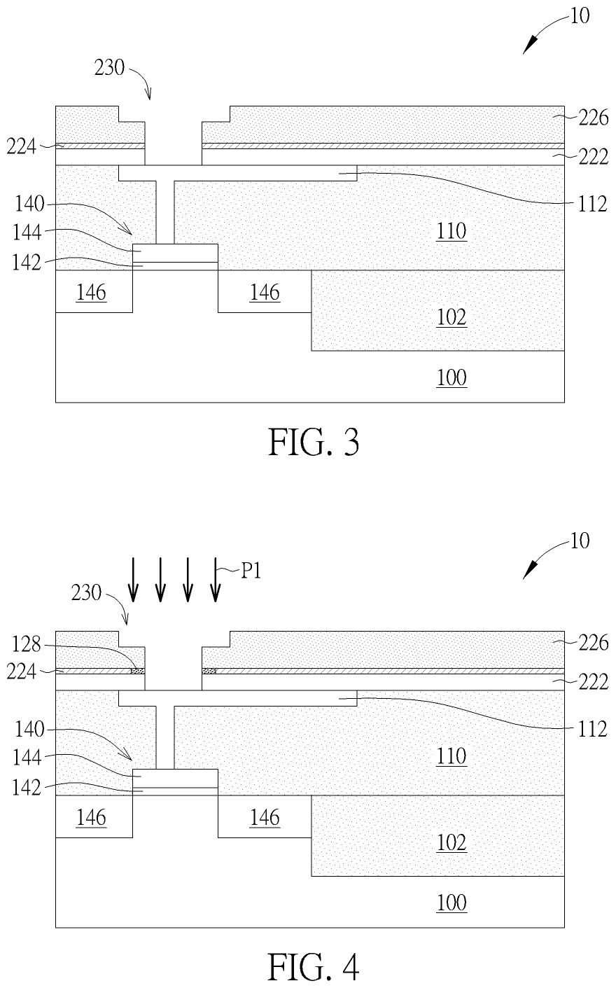

As shown in FIG. 3, an etching process such as a dry etching process with plasma is performed through a mask layer (not shown in the drawings). The etching process is carried out by using the etching stop material layer 222 as an etching blocker, to sequentially etch the low-k dielectric material layer 226, the conductive material layer 224, and the etching stop material layer 222, to form at least one through hole 230 in the low-k dielectric material layer 226, the conductive material layer 224 and the etching stop material layer 222. Accordingly, a portion of the top surface of the plug 112 is exposed from the bottom of the through hole 230, and a portion of the low-k dielectric material layer 226, the conductive material layer 224 and the etching stop material layer 222 are exposed from a sidewall of the through hole 230. Then, the mask layer is completely removed.

As shown in FIG. 4, an insulation process P1 is performed on an exposed portion of the conductive material layer 224 revealing from the sidewall of the through hole 230 to insulate the exposed portion, thereby forming the first insulator 128. The insulation process P1 may include different steps based on various materials of the conductive material layer 224. For example, the insulation process P1 for example includes an oxidation process, as the conductive material layer 224 includes a metal material like Ti, Ta, Al, Cu or W, to form the first insulator 128 including a metal oxide like TiO₂, TaO₂, Al₂O₃ or CuO. Alternatively, the insulation process P1 may also include a nitridizing process, as the conductive material layer 224 includes a metal material like Ti, Ta, Al, Cu or W, to form the first insulator 128 including a metal nitride like aluminum nitride or copper nitride, but not limited thereto. On the other hand, the insulation process P1 may also include an oxidation process and/or a nitridizing process, as the conductive material layer 224 includes a semiconductor material like doped silicon, doped germanium, indium zinc oxide or indium gallium zinc oxide, to form the first insulator 128 including an oxide semiconductor/a nitride semiconductor like silicon oxide, germanium oxide, silicon nitride or germanium nitride, but is not limited thereto.

Following these, at least one deposition process is performed, to form a conductive material (not shown in the drawings) filling in the through hole 230 and further covering the top surface of the low-k dielectric material layer 226. Then, a planarization process is performed, to remove the conductive material outside the through hole 230, thereby forming the first conductive structure 130 as shown in FIG. 1, and simultaneously forming the low-k dielectric layer 126, the etching stop layer 122 and the conductive layer 124, with the low-k dielectric layer 126 and the etching stop layer 122 together forming the dielectric layer 120 also shown in FIG. 1. In one embodiment, the conductive material for example includes a barrier layer (not shown in the drawings) conformally covering the sidewall of the through hole 230, and a metal layer (not shown in the drawings) filling up the through hole 230, but not limited thereto.

People well known in the arts should easily realize the semiconductor device and the fabricating method thereof in the present disclosure are not limited to what is shown in the aforementioned embodiment, and may further include other examples. The following description will go into detail the different embodiments of the semiconductor device and the fabricating method thereof in the present disclosure. To simplify the description, the following description will elaborate the dissimilarities among the different embodiments and the identical features will not be redundantly described. In order to compare the differences between the embodiments easily, the identical components in each of the following embodiments are marked with identical symbols.

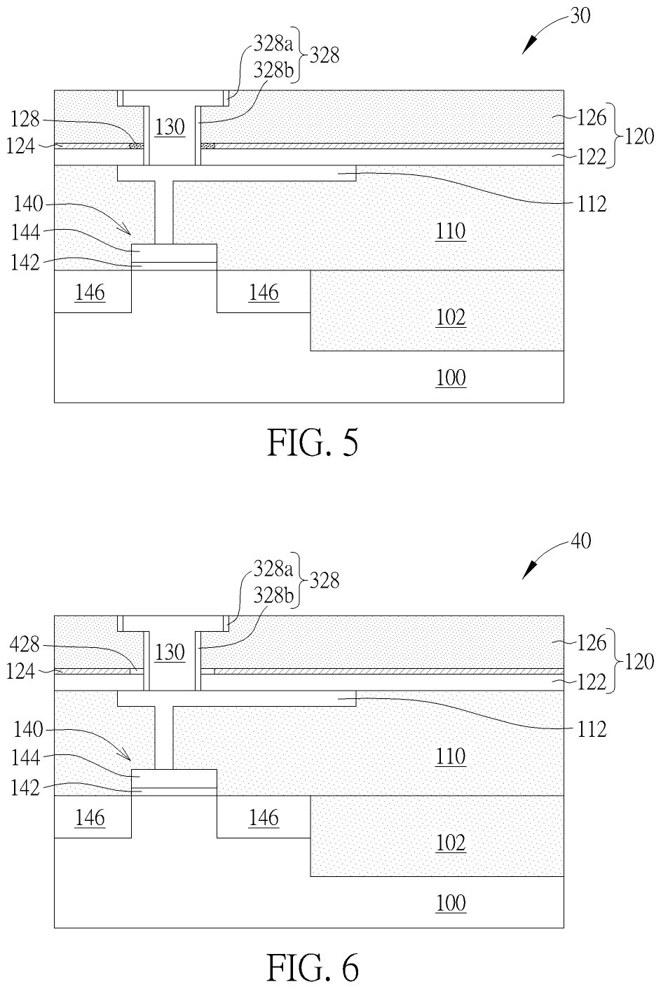

Please refer to FIG. 5, which illustrates a semiconductor device 30 according to a second embodiment of the present disclosure. The structure of the semiconductor device 30 of the present embodiment is substantially the same as that of the aforementioned first embodiment, and all the similarities of the two embodiments will not be redundantly described hereinafter. The difference between the present embodiment and the aforementioned first embodiment is mainly in that a second insulator 328 is additionally arranged in the semiconductor device 30.

Precisely speaking, the second insulator 328 is disposed on a sidewall of the conductive structure 130, covering the first insulator 128. As shown in FIG. 5, the second insulator 328 for example includes a first portion 328a disposed on a via sidewall of the dual damascene structure, and a second portion 328b disposed on a trench sidewall of the dual damascene structure, thereby serving as a discontinuous structure as a whole. The second portion 328b of the second insulator 328 directly contacts the first insulator 128 and is disposed between the conductive structure 130 and the first insulator 128, to further insulate the conductive layer 124 from the conductive structure 130 in an effective manner, without excessively increasing the dielectric constant of the dielectric layer 120.

In one embodiment, the second insulator 328 for example includes silicon oxide, silicon nitride, silicon oxynitride or silicon carbonitride, and preferably includes a material different from that of the first insulator 128, but not limited thereto. The formation of the second insulator 328 is for example accomplished by performing a deposition process and an etching back process, but not limited thereto. As an example, after forming the structure as shown in FIG. 4, an insulating material is uniformly formed on surfaces of the through hole 230, and the insulating material covering on the horizontal surface of the through hole 230 is removed through the etching back process. Accordingly, the insulating material covering on the vertical surface of the through hole 230 is remained, to form the discontinuous structure of the second insulator 328.

With these arrangements, the semiconductor device 30 of the present embodiment also enables to disperse or to guide the unstable charges accumulated on the interconnection (conductive structure 130) to the external environment or to ground via the conductive layer 124 within the IMD layer (namely the dielectric layer 120), thereby reducing the possibility of structural damages caused by plasma used in the back-end process. In addition, the second insulator 328 is additionally disposed in the semiconductor device 30, and the first insulator 128 and the second insulator 328 are together arranged between the conductive layer 124 and the conductive structure 130, to further insulate the conductive layer 124 and the conductive structure 130, and to prevent the conductive layer 124 from directly connecting the conductive structure 130 that leads to short circuit. In this way, the semiconductor device 30 of the present embodiment also enables to improve the Antenna effect, and the AR of the semiconductor device 30 is no longer required to meet the existing AR limitation like AR2000. Accordingly, the semiconductor device 30 of the present embodiment is able to gain improved reliability and yield, and thus to achieve better functions and performances.

Please refer to FIG. 6, which illustrates a semiconductor device 40 according to a third embodiment of the present disclosure. The structure of the semiconductor device 40 of the present embodiment is substantially the same as that of the aforementioned second embodiment, and all the similarities of the two embodiments will not be redundantly described hereinafter. The difference between the present embodiment and the aforementioned second embodiment is mainly in that a first insulator 428 of the present embodiment includes an air gap layer.

Precisely speaking, the formation of the first insulator 428 is accomplished by partially removing the conductive material layer 224 as shown in FIG. 3, to form an air gap retreating from the vertical sidewall of the through hole 230, and performing a deposition process and an etching back process, to form the second insulator 328. Meanwhile, while forming the second insulator 328, the second portion 328b of the second insulator 328 seals the air gap without filling therein, to form the air gap layer serving as the first insulator 428. Accordingly, the first insulator 428 having the air gap layer, and the second insulator 328 having the insulating material will together insulate the conductive layer 124 from the conductive structure 130 in a more effective manner without increasing the dielectric constant of the dielectric layer 120.

With these arrangements, the semiconductor device 40 of the present embodiment also enables to disperse or to guide the unstable charges accumulated on the interconnection (conductive structure 130) to the external environment or to ground via the conductive layer 124 within the IMD layer (namely the dielectric layer 120), thereby reducing the possibility of structural damages caused by plasma used in the back-end process. According to the present embodiment, the first insulator 428 having the air gap layer, and the second insulator 328 having the insulating material are both arranged between the conductive layer 124 and the conductive structure 130 in the semiconductor device 40, to together insulate the conductive layer 124 from the conductive structure 130, and to prevent the conductive layer 124 from directly connecting the conductive structure 130 that leads to short circuit. In this way, the semiconductor device 40 of the present embodiment also enables to improve the Antenna effect, and the AR of the semiconductor device 40 is no longer required to meet the existing AR limitation like AR2000. Accordingly, the semiconductor device 40 of the present embodiment is able to gain improved reliability and yield, and thus to achieve better functions and performances.

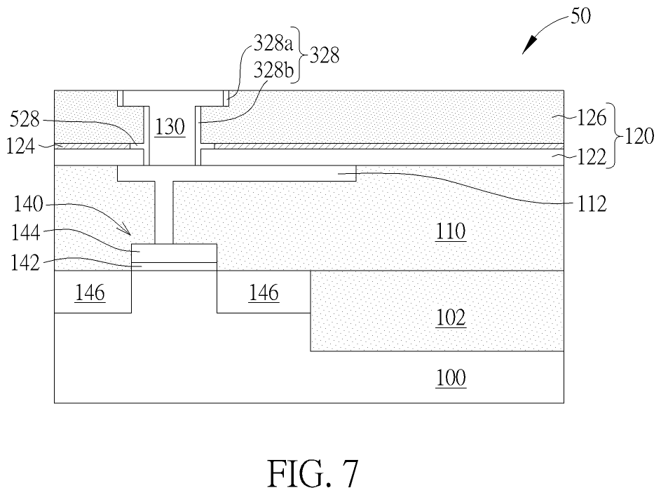

Please refer to FIG. 7, which illustrates a semiconductor device 50 according to a fourth embodiment of the present disclosure. The structure of the semiconductor device 50 of the present embodiment is substantially the same as that of the aforementioned second embodiment, and all the similarities of the two embodiments will not be redundantly described hereinafter. The difference between the present embodiment and the aforementioned second embodiment is mainly in that a first insulator 528 and the second insulator 328 of the semiconductor device 50 include the same insulating material.

Precisely speaking, the formation of the first insulator 528 is also accomplished by partially removing the conductive material layer 224 as shown in FIG. 3, to form the air gap retreating from the vertical sidewalls of the through hole 230, and performing a deposition process and an etching back process, to simultaneously form the second insulator 328 and the first insulator 528. It is noted that, the deposition conditions of the deposition process in the present embodiment have been adjusted in further, so that, the insulating material will fill in the air gap to form the first insulator 528, and further covers the surfaces of the through hole 320 to form the first portion 328a and the second portion 328b of the second insulator 328 after the subsequent etching back process. The second portion 328b of the second insulator 328 directly contacts the first insulator 528, and which are integrated formed with the first insulator 528, as shown in FIG. 7. Accordingly, through arranging the first insulator 528 and the second insulator 328 both having the same insulating material in the same fabricating process, the conductive layer 124 will be still effectively insulated from the conductive structure 130 without increasing the dielectric constant of the dielectric layer 120.

With these arrangements, the semiconductor device 50 of the present embodiment also enables to disperse or to guide the unstable charges accumulated on the interconnection (conductive structure 130) to the external environment or to ground via the conductive layer 124 within the IMD layer (namely the dielectric layer 120), thereby reducing the possibility of structural damages caused by plasma used in the back-end process. According to the present embodiment, the first insulator 528 and the second insulator 328 having the same insulating material are both arranged between the conductive layer 124 and the conductive structure 130 in the semiconductor device 50, to further insulate the conductive layer 124 and the conductive structure 130 in an effective manner, and to prevent the conductive layer 124 from directly connecting the conductive structure 130 that leads to short circuit. In this way, the semiconductor device 50 of the present embodiment also enables to improve the Antenna effect, and the AR of the semiconductor device 50 is no longer required to meet the existing AR limitation like AR2000. Accordingly, the semiconductor device 50 of the present embodiment is able to gain improved reliability and yield, and thus to achieve better functions and performances.

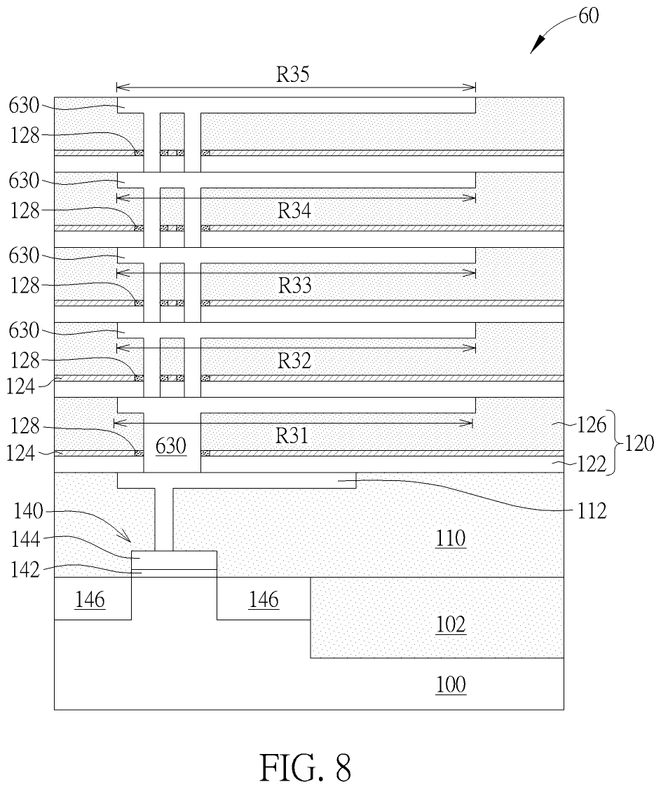

Please refer to FIG. 8, which illustrates a semiconductor device 60 according to a fifth embodiment of the present disclosure. The structure of the semiconductor device 60 of the present embodiment is substantially the same as that of the aforementioned first embodiment, and all the similarities of the two embodiments will not be redundantly described hereinafter. The difference between the present embodiment and the aforementioned first embodiment is mainly in that the semiconductor device 60 additionally includes a plurality of dielectric layers 120 on the dielectric layer 110, and each of the dielectric layers 120 includes a conductive structure 630 disposed therein.

Precisely speaking, as shown in FIG. 8, each of the dielectric layers 120 includes the etching stop layer 122 and the low-k dielectric layer 126 stacked sequentially, and each conductive structure 630 for example includes any components being made of a conductive material such as a conductive line, a plug, a metal line or a RDL, but is not limited thereto. It is noted that, each of the dielectric layers 120 further includes a conductive layer 124 disposed in the middle, between the etching stop layer 122 and the low-k dielectric layer 126, and which also includes the first insulator 128 between each conductive structure 630 and each conductive layer 124 within each dielectric layer 120. People skilled in the arts should easily realize the practical number of the dielectric layers 120 and/or the precise pattern or the surface area of the each conductive structure 630 in the present embodiment are only for exemplification, and which may be further adjusted based on practical product requirements and will not be limited by what is shown in FIG. 8. For example, in another embodiment, one layer, two layers or multilayer layers of the dielectric layers 120 may be optionally disposed on the dielectric layer 110, with each conductive structure 630 disposed within each of the dielectric layers 120 having various exposing areas R31, R32, R33, R34, R35 or various required patterns. Also, in another embodiment, the second insulator 328 as shown in FIG. 5, the first insulator 428 and the second insulator 328 as shown in FIG. 6, or the first insulator 528 and the second insulator 328 as shown in FIG. 7 may be additionally arranged in each of the dielectric layers 120, but not limited thereto.

With these arrangements, the dielectric layer 110 is also configured as an ILD layer of the semiconductor device 60 when the plug 112 serving as a contact plug or a M0 interconnection of the semiconductor device 60, and each dielectric layer 120 are respectively configured as an IMD layer of the semiconductor device 60 when the conductive structure 630 within each dielectric layer 120 respectively serving as a M1 metal interconnection, a second-layer metal interconnection (M2), a third-layer metal interconnection (M3) to a nₜₕ-layer metal interconnection (with n being a positive integer greater than 3). Accordingly, through arranging the conductive layer 124 within the middle of each IMD layer, the semiconductor device 60 of the present embodiment also enables to dispense the unstable charges accumulated on each interconnection (namely, the conductive structure 630), but also to increase the tolerance of the semiconductor device 60 against to the Antenna effect, thereby further reducing the possibility to get structural damage caused by plasma in the back-end process.

In this way, the semiconductor device 60 of the present embodiment is also able to gain a dramatically improved reliability and yield, and which is no longer required to meet the existing AR limitation like AR2000.

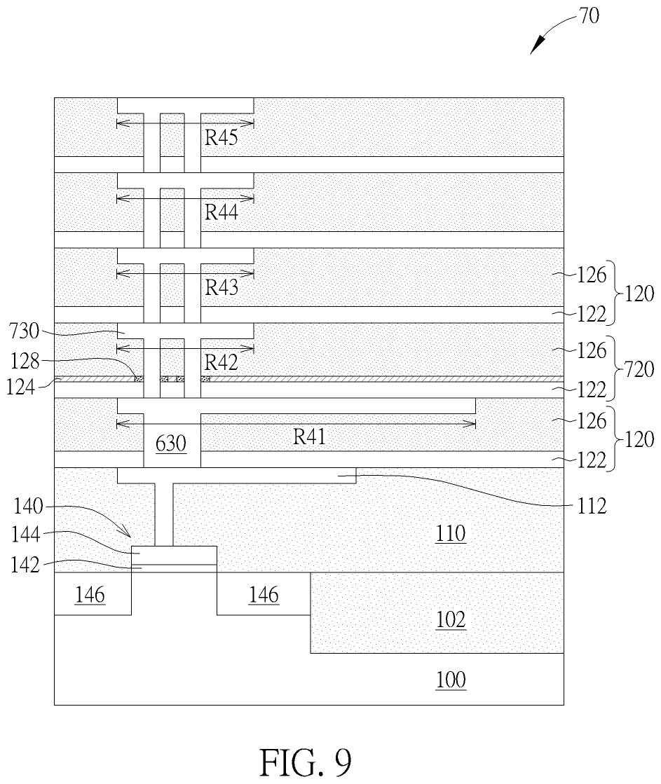

Please refer to FIG. 9, which illustrates a semiconductor device 70 according to a sixth embodiment of the present disclosure. The structure of the semiconductor device 70 of the present embodiment is substantially the same as that of the aforementioned first embodiment, and all the similarities of the two embodiments will not be redundantly described hereinafter. The difference between the present embodiment and the aforementioned first embodiment is mainly in that the semiconductor device 70 additionally includes a plurality of dielectric layers 120, 720, and each of the dielectric layers 120, 720 includes a conductive structure 630, 730 disposed therein.

Precisely speaking, as shown in FIG. 9, each of the dielectric layers 120, 720 includes the etching stop layer 122 and the low-k dielectric layer 126 stacked sequentially. It is noted that, at least one of the dielectric layers 720 additionally includes the conductive layer 124 disposed therein, with the conductive layer 124 being preferably disposed in the dielectric layer 720 above the conductive structure 630 having a relative greater exposing area R41. The conductive structures 630, 730 for example includes any components being made of a conductive material such as a conductive line, a plug, a metal line or a RDL, but is not limited thereto, wherein the conductive structure 630 has a greater exposing area R41 than that (such as the exposing area R42, R43, R44, R45) of other conductive structures 730, but not limited thereto.

People skilled in the arts should easily realize the precise pattern or the exposing area R41, R42, R43, R44, R45 of each conductive structure 630, 730 in the present embodiment are only for exemplification, and which may be further adjusted based on practical product requirements and will not be limited by what is shown in FIG. 9. Also, the practical disposing number and/or the disposing location of the conductive layer 124 may also be further adjusted based on practical product requirements. Otherwise, the second insulator 328 as shown in FIG. 5, the first insulator 428 and the second insulator 328 as shown in FIG. 6, or the first insulator 528 and the second insulator 328 as shown in FIG. 7 may also be additionally arranged between each conductive layer 124 and each conductive structure 630, 730, but not limited thereto.

With these arrangements, the dielectric layer 110 is also configured as an ILD layer of the semiconductor device 70 when the plug 112 serving as a contact plug or a zero-layer metal interconnection (M0) of the semiconductor device 70, and each dielectric layer 120, 720 are respectively configured as an IMD layer of the semiconductor device 70 when each conductive structure 630, 730 within each dielectric layer 120, 720 sequentially serving as a M1 metal interconnection, a M2 interconnection, a M3 interconnection to a Mn interconnection (with n being a positive integer greater than 3). Accordingly, through arranging the conductive layer 124 within the middle of at least one of the IMD layers, the semiconductor device 70 of the present embodiment still enables to disperse or to guide the unstable charges accumulated on each interconnections (such as the conductive structures 630, 730) to the external environment or to ground, reducing the possibility to get structural damage caused by plasma in the back-end process. In this way, the semiconductor device 70 of the present embodiment is also able to gain a dramatically improved reliability and yield, and which is no longer required to meet the existing AR limitation like AR2000.

Overall speaking, according to the semiconductor device and the fabricating method thereof, a conductive layer is arranged in at least one IMD layer, and a first insulator is further arranged between the conductive layer and the interconnection, to insulate the conductive layer and the interconnection in an effective manner without increasing the dielectric constant of the IMD layer. Then, the unstable charges accumulated on the interconnection may be dispersed or guided to the external environment or to ground via the conductive layer, thereby dramatically reducing the possibility to get structural damage caused by plasma in the back-end process. Preferably, the conductive layer and the first insulator are disposed in the middle of one IMD layer over the interconnection having a relative greater exposing area, or are disposed in each IMD layer, to disperse or to guide the unstable charges accumulated on the interconnection to the external environment or to ground in a further effective manner. Thus, the semiconductor device of the present disclosure enables to dramatically improve the Antenna effect under an increasing AR, and also, to gain an optimized reliability and yield.

It is also noted that although the aforementioned embodiment are all exemplified on a semiconductor device having a metal interconnection layer, people skilled in the art should easily understand that the method of guiding the unstable charges by additionally arranging a conductive layer and an insulator in the present disclosure may also be applied to other dielectric layers of a semiconductor device having a conductive structure, to improve structural reliability and yield thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
at least one dielectric layer, comprising a stacked structure comprising a low-k dielectric layer and an etching stop layer;
a conductive structure, disposed in the at least one dielectric layer;
a conductive layer, disposed in the stacked structure, between the low-k dielectric layer and the etching stop layer; and
a first insulator disposed between the conductive layer and the conductive structure.

2. The semiconductor device according to claim 1, further comprises a second insulator disposed on a sidewall of the conductive structure, covering the first insulator.

3. The semiconductor device according to claim 2, wherein the second insulator comprises a discontinuous structure.

4. The semiconductor device according to claim 2, wherein the first insulator and the second insulator comprise different insulating materials.

5. The semiconductor device according to claim 4, wherein the first insulator comprises an air gap layer.

6. The semiconductor device according to claim 2, wherein the first insulator and the second insulator comprise a same insulating material.

7. The semiconductor device according to claim 1, wherein a dielectric constant of the low-k dielectric layer is smaller than a dielectric constant of the etching stop layer.

8. The semiconductor device according to claim 1, wherein a thickness of the first insulator is between 50 angstroms and 300 angstroms.

9. The semiconductor device according to claim 1, wherein the conductive layer comprises a semiconductor material or a metal material.

10. The semiconductor device according to claim 1, further comprising:
a plurality of the dielectric layers stacked on one over another; and
a plurality of the conductive structures, respectively disposed in the plurality of the dielectric layers, wherein each of the plurality of the dielectric layers comprises the conductive layer disposed in a middle thereof, and the first insulator is disposed between the conductive layer and each of the conductive structures.

11. The semiconductor device according to claim 1, further comprising:
a plurality of the dielectric layers stacked on one over another; and
a plurality of the conductive structures, respectively disposed in the plurality of the dielectric layers, wherein one of the plurality of the dielectric layers comprises the conductive layer disposed in a middle thereof, and the first insulator disposed between the conductive layer and the conductive structure disposed in the one of the plurality of dielectric layers.

12. The semiconductor device according to claim 1, further comprising:
a substrate;
a gate structure, disposed on the substrate; and
a plug surrounded by an interlayer dielectric layer on the substrate, below the at least one dielectric layer, wherein the plug directly contacts the conductive structure.

13. A method of fabricating a semiconductor device, comprising:
forming at least one dielectric layer, the at least one dielectric layer comprising a stacked structure comprising a low-k dielectric layer and an etching stop layer;
forming a conductive structure in the at least one dielectric layer;
forming a conductive layer in the stacked structure, between the low-k dielectric layer and the etching stop layer; and
forming a first insulator between the conductive layer and the conductive structure.

14. The method of fabricating the semiconductor device according to claim 13, further comprising:
sequentially forming an etching stop material layer, a conductive material layer, and a low-k dielectric material layer;
forming a through hole in the low-k dielectric material layer, the conductive material layer and the etching stop material layer; and
forming the first insulator through the through hole; and
forming the conductive structure filled in the through hole.

15. The method of fabricating the semiconductor device according to claim 14, forming the first insulator comprising:
performing an oxidation process, to oxidize a portion of the conductive material layer into the first insulator, wherein the conductive material layer comprises a metal material.

16. The method of fabricating the semiconductor device according to claim 14, forming the first insulator comprising:
performing a nitridizing process, to nitridize a portion of the conductive material layer into the first insulator, wherein the conductive material layer comprises a semiconductor material.

17. The method of fabricating the semiconductor device according to claim 14, forming comprising:
forming a second insulator on the first insulator, between the conductive structure and the first insulator.

18. The method of fabricating the semiconductor device according to claim 17, forming the second insulator further comprising:
partially removing the conductive material layer, to form an air gap; and
performing a deposition process, to form the first insulator in the air gap, and to form the second insulator on a sidewall of the through hole.

19. The method of fabricating the semiconductor device according to claim 17, forming the second insulator further comprising:
partially removing the conductive material layer, to form an air gap; and
performing a deposition process, to form the second insulator on a sidewall of the through hole, and to form the first insulator comprising an air gap layer.

20. The method of fabricating the semiconductor device according to claim 13, forming comprising:
providing a substrate;
forming a gate structure on the substrate; and
forming a plug surrounded by an interlayer dielectric layer on the substrate, below the at least one dielectric layer, wherein the plug directly contacts the conductive structure.
